(19) United States
(12) Patent Application Publication
(10) Pub. No.: US 2010/0259263 A1
(43) Pub. Date: Oct. 14, 2010

(54) LONGITUDINAL REGISTRATION OF ANATOMY IN MAGNETIC RESONANCE IMAGING

(76) Inventors: Dominic Holland, La Jolla, CA (US); Anders M. Dale, La Jolla, CA (US)

Correspondence Address: FISH & RICHARDSON, PC, P.O. BOX 1022, MINNEAPOLIS, MN, 55440-1022, US

(21) Appl. No.: 12/742,642

(22) PCT Filed: Nov. 14, 2008
(86) PCT No.: PCT/US08/83692

§ 371 Date: May 26, 2010

Related U.S. Application Data
(60) Provisional application No. 60/988,014, filed on Nov. 14, 2007.

(51) Int. Cl. G01R 33/48

(52) U.S. Cl. 324/310

(57) ABSTRACT

Devices, systems, and techniques relate to detecting volumetric changes in imaged structures over time, including devices, systems and techniques that enable precise registration of structures (e.g., brain areas) after large or subtle deformations, allowing precise registration at small spatial scales with a low boundary contrast.

### PRIORITY CLAIM AND REFERENCE TO RELATED APPLICATIONS

This application claims priority from U.S. Provisional Application Ser. No. 60/988,014 entitled “LONGITUDINAL REGISTRATION OF ANATOMY IN MAGNETIC RESONANCE IMAGING” and filed on Nov. 14, 2007, the entire disclosure of which is incorporated herein by reference.

### FEDERALLY-SPONSORED RESEARCH OR DEVELOPMENT

The invention was made with government support under NIH Grant Nos. AG022381-03, EB000790 and AG024904-02 awarded by National Institutes of Health. The government has certain rights in the invention.

### BACKGROUND

This application relates to magnetic resonance imaging (MRI) and processing of images, such as magnetic resonance (MR) images.

Imaging through MRI techniques is well known and has been widely applied in imaging applications in medical, biological and other fields. In essence, a typical MRI technique produces an image of a selected body part of an object under examination by manipulating the magnetic spins in a body part and processing measured responses from the magnetic spins. A MRI system may include hardware to generate different magnetic fields for imaging, including a static magnetic field along a z-direction to polarize the magnetic spins, gradient fields along mutually orthogonal x, y, or z directions to spatially select a body part for imaging, and a radiofrequency (RF) magnetic field to manipulate the spins.

The brain of a person can undergo changes in shape, often accompanied with changes in tissue properties, during development in neonates, normal aging, and in many neurological disorders. MRI techniques can be used to measure structural changes in the brain. A deformation field includes a three-dimensional displacement of all voxels or volume elements of an MRI image in an MRI scan. Information in the deformation field can be used to diagnose various conditions, for example, by accurately calculating the volume changes to assess whether a pathological change occurs.

Structural changes over time in an individual's brain can be subtle, including changes associated with disorders such as Alzheimer's Disease.

### SUMMARY

The devices, systems, and techniques described herein relate to detecting volumetric changes in imaged structures over time, including devices, systems and techniques that enable precise registration of structures (e.g., brain areas) after large or subtle deformations, allowing precise registration at small spatial scales with a low boundary contrast.

In one aspect, a method for imaging a subject includes correcting first and second images of a subject and registering the first image to the second image; obtaining a deformation field that maps each element in the first image into a corresponding element in the second image by reducing a mapping error from the first image to the second image; and calculating a volume of at least one region within the subject in the second image and using the deformation field to calculate a volume of the same at least one region within the subject in the first image.

Implementations may include one or more of the following features. The first and second images includes images measured with magnetic resonance imaging, x-ray computed tomography, ultrasound, single photon emission computed tomography, or positron emission tomography. The subject includes a human, a primate, or a rodent.

Registering includes performing an affine registration prior to a nonlinear registration. The affine registration is a mapping between two images that uses an affine transformation, which is a mapping between two vector spaces that can include rotations, scalings, and translations. Affine transformations preserve co-linearity between points and ratios of distances along a line. In implementing the affine registration prior to the nonlinear registration, the images cam be smoothed as part of registering the first image to the second image. Registering includes iteratively smoothing the images and performing a nonlinear registration of the first image to the second image.

Minimizing includes calculating a Hessian of a function that represents the mapping error and using a linear algebraic technique on the Hessian to obtain the deformation field. The linear algebraic technique includes conjugate gradients squared (CGS), generalized minimal residuals (GMRES), or biconjugate gradients stabilized method (Bi-CGSTAB).

Minimizing is computationally fast. Correcting includes standardizing intensities of the images to a uniform intensity scale and locally rescaling the intensities in the first or the second image to conform with inhomogenieties in the other image. Correcting can include correcting geometric image distortions.

The at least one region within the subject is identified by using an automatic or manual segmentation technique. The at least one region includes part of a brain, a liver, a knee, a heart, an abdomen, or an organ. The at least one region includes part of a hippocampus, a middle temporal gyrus, an inferior temporal gyrus, a fusiform gyrus, an entorhinal cortex, a ventricle, or an amygdala.

A volumetric change in the first and second images of the region within the subject is quantified. The method is used to detect pathology or a disease can be detected. The disease includes a neurodegenerative disorder, a cancer, an inflammatory disease, or an immunologic disease. The neurodegenerative disorder includes Alzheimer's Disease.

The method is used to assess an efficacy of a treatment administered to the subject. The treatment includes a drug or radiation therapy. Groups of subjects are evaluated with the method.

A visualization of the volumetric change between the first and second images of the region within the subject is produced. The visualization includes a color image whose color represents the volumetric change.

The first image is measured at a time before or after the second image and the time includes days, weeks, months, and years.

The contrasts of the first and second images include contrasts based on different image weightings or modalities.

The mapping error includes a function that includes terms representing gradients of displacements at each voxel of one image of the pair, amplitudes of the displacements, a quality of the registration, or other quantities.

In another aspect, a function is defined that represents a registration error between of a pair of images that, when minimized, corrects for at least one of relative intensity variation or relative structural deformation between the images; on a computer, minimizing the function in a way that is computationally fast; and producing a deformation field that registers one image of the pair to the other image of the pair.

Implementations may include one or more of the following features. A volumetric change between the images is quantified. The function includes terms representing gradients of displacements at each voxel of one image of the pair, amplitudes of the displacements, a quality of the registration, or other quantities.

In another aspect, a method for diagnosing or monitoring a progress of a pathology or a disease includes obtaining a first image of a subject and a second image of the subject; on a computer, correcting the first and second images and registering the first image to the second image; obtaining a deformation field that maps each element in the first image into a corresponding element in the second image by minimizing, on a computer, a mapping error from the first image to the second image; on a computer, calculating a volume of at least one region within the subject in the second image and using the deformation field to calculate a volume of the same at least one region within the subject in the first image; and quantifying a volumetric change in the first and second images of the region within the subject, in which the volumetric change at least in part determines a presence or a change in the pathology or the disease.

Implementations may include one or more of the following features. Determining a presence or a change includes comparing the volumetric change with data of an expected change in the pathology or the disease. An effect of a compound on a specified brain region can be determined, in which the volumetric change indicates the efficacy of the compound.

In another aspect, a computer program product, encoded on a computer-readable medium, is operable to cause a data processing apparatus to perform operations including: obtaining a first image of a subject and a second image of the subject, in which the first image is measured at a different time than the second image; correcting the first and second images; registering the first image to the second image; obtaining a deformation field that maps each element in the first image into a corresponding element in the second image by minimizing a function that represents a mapping error between the first and second images; and calculating a volume of at least one region within the subject in the second image and using the deformation field to calculate a volume of the same at least one region within the subject in the first image.

Implementations may include one or more of the following features. The computer program product includes operations for quantifying a volumetric change in the first and second images of the region within the subject.

In another aspect, an MRI system includes a magnetic resonance system configured to provide a first image and a second image of a subject. The system also includes a data processing system configured to correct the first and second images; register the first image to the second image; obtain a deformation field that maps each element in the first image into a corresponding element in the second image by minimizing a function that represents a mapping error between the first and second images; and calculate a volume of at least one region within the subject in the second image and using the deformation field to calculate a volume of the same at least one region within the subject in the first image.

Implementations may include one or more of the following features. The system includes a data processing system configured to quantify a volumetric change in the first and second images of the region within the subject.

For example, imaging (e.g., magnetic resonance imaging) is performed in which two images of an object are obtained at different times (e.g., weeks or months apart). These images are linearly aligned and the intensities of the images can be standardized (e.g., to a uniform intensity scale) and can be rescaled locally in one image so as to conform with inhomogeneities (e.g., the scanner-induced inhomogeneities) in the other image. Information can be extracted by using the remaining misalignment between the two images to infer structural deformations from subregions of the object.

The structural deformation in the object can be represented in a color-coded graphics, in which different colors represent different structural deformations. The color-coded graphics can be used to aid diagnosis of a condition of the object.

In yet another aspect, a method for MRI imaging includes performing two MRI images of an object at different times; linearly aligning the two MRI images; standardizing intensities of the two MRI images to a uniform intensity scale; locally rescaling the intensities in one MRI image so as to conform with the scanner-induced inhomogenieties in the other MRI image; and extracting information on the remaining misalignment between the two MRI images to represent structural deformation from subregions of the object.

These and other aspects and their implementations are described in detail in the description, the drawings, and the claims.

### BRIEF DESCRIPTION OF DRAWINGS

FIGS. 1A-B are schematics of a magnetic resonance system.

FIG. 2 is a flowchart.

FIGS. 3A-C are magnetic resonance images of a human brain displayed with a color overlay that represents local intensity scaling.

FIGS. 4A-B are images representing models of volume changes.

FIGS. 5A-C and 6A-C are magnetic resonance images of a human brain displayed with color overlays that represent tissue segmentation (FIGS. 5A and 6A) and percentage volume change (FIGS. 5B-C and 6B-C).

FIGS. 7A-C are graphs comparing volumes in the left hippocampus of normal subjects and subjects with mild cognitive impairment (MCI) or Alzheimer's Disease (AD).

FIG. 8 is a sagittal magnetic resonance image of a subject with a pituitary gland tumor.

FIG. 9 is an image of fractional isotropy of white matter tracts of a post-resection epileptic subject.

FIG. 10 is a series of registered magnetic resonance images of a primate.

Like reference symbols in the various drawings indicate like elements.

### DETAILED DESCRIPTION

The devices, systems, and techniques described herein can be implemented for MRI-based analysis, diagnostics and treatment, including providing a fast, robust processing of serial images (e.g., MRI scans) that allows detection of anatomical changes (e.g., volumetric changes), including changes of small regions of interest (ROIs), and quantification of these changes over time.

Brain development, aging, and many neurological and psychiatric disorders are often associated with structural changes of the brain. Individual disorders can have unique patterns of tissue deformation and evolution of tissue atrophy or hypertrophy, though with variability across subjects. To discriminate pathologies, especially for early diagnosis, patterns in the onset and development of change need to be understood quantitatively.

For example, in patients who are suspected to have Alzheimer's Disease (but have not yet been diagnosed), quantifying volumetric changes over time within specific brain regions can be a powerful diagnostic tool that permits a health care provider (e.g., a neurologist) to compare the degree and progression of volumetric changes of the patient with documented changes of others who have been diagnosed previously with Alzheimer's Disease. Regional volumetric changes can include, for example, ventricular expansion, loss of cortical surface in specific areas, such as shrinkage of hippocampi and amygdalae.

The present systems and techniques can also be used detect nascent tumors in sequential images and measure the rates of change (e.g., volumetric change) through natural growth or in response to radiation or drug therapy.

The present techniques, which can be performed within a short computation times, can also be used to reveal fine detail in patterns of tissue loss and to distinguish cortical surface loss from white matter loss. Furthermore, the present technique can be used to specify regions of interest, e.g., the hippocampus, the amygdala, the caudate nucleus, and accurately determine a volumetric change for each region as a function of time, and the pattern of deformation within these regions.

In some examples, two MR scans of the object of interest, e.g., a subject's full head, can be taken at different times (e.g., weeks apart, months apart, years apart). The goal is to find precisely the structural changes that have taken place in the intervening time between the two MR scans. In general, the images will not be aligned, and may be different in shape or contrast, due to, for example, expansion and shear from the scanner, and local and overall intensities, due to different scanner settings and inhomogeneities in the scanner magnetic fields. These inconsistencies can be rectified by linearly aligning the images, standardizing the intensities to a uniform scale, and then locally rescaling the intensities in one image to conform with the scanner-induced inhomogeneities in the other.

Any remaining misalignment can be considered the result of structural deformations (e.g., subregions expanding or contracting or having moved, changed shape, size, or image intensity), which could be due to pressure from other regions, nucleation of new material, growth, or decay. This misalignment can be expressed as displacements of individual voxels (e.g., as represented by a three-dimensional deformation field) that map one image into the other. Hence, the deformation field represents a mapping from a voxel location in one image to a corresponding location in another image and, as an example, can transform cubic voxels into displaced hexahedra. Such a map or deformation field can be obtained with a high degree of accuracy (e.g., sub-millimeter) that is limited only by native scan resolution in cases of non-nucleation. When nucleation occurs, inherently topologically distinct objects are present (e.g., a tumor in a later image that was not present in the first image), but the deformation field will nonetheless capture its location. To find the deformation field, a cost function that depends on all the three-dimensional voxel displacements can be evaluated. The value of the cost function represents any mapping error between images.

The displacement field, in turn, can be used to find the new locations of the corners of the voxels, which in general can become irregular hexahedra. The volume of each hexahedron can be calculated and summed over a region of interest to give the new tissue volume.

The displacement field can also be expressed as an expansion of basis functions, e.g., the discrete cosine, and solving the cost function for the expansion coefficients.

### Magnetic Resonance System

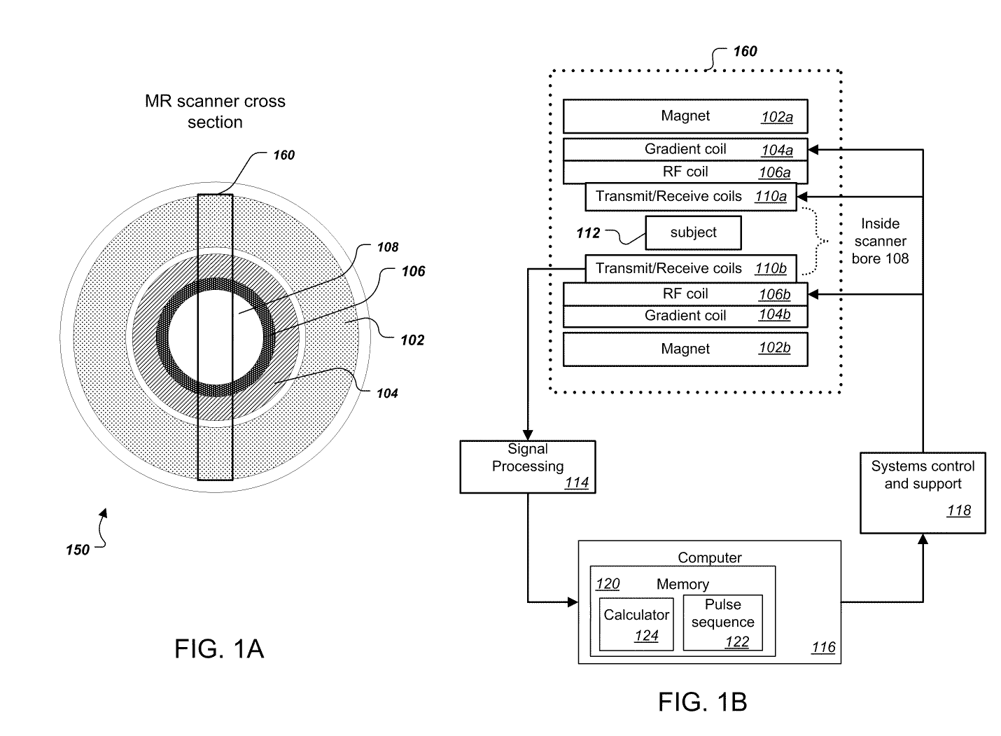

In some examples, magnetic resonance (MR) images are used with the devices, systems, and techniques described herein. FIG. 1A shows a cross-section 150 of an exemplary MR scanner that includes a magnet 102, a gradient coil 104, a radiofrequency (RF) coil 106 (e.g., a head coil), and a magnet bore 108.

The magnet 102 is designed to provide a constant, homogeneous magnetic field and can have a field strength between about 0.5 Tesla and about 11 Tesla, for example, 1.5 T, 3T, 4.7T, 7T, 9.4 T. The gradient coil 104 can include one, two, or three gradient coils that are designed to provide up to three orthogonal magnetic gradients whose amplitudes are controlled and used to acquire data of a desired region of a subject. For example, these gradients can be used to acquire image or spectroscopic data of a desired slice by generating an encoded and slice-selective magnetic field.

The RF coil 106 can be an integrated transceiver coil or can include both an RF transmit coil and an RF receive coil for transmitting and receiving RF pulses.

A slice 160 through the cross-section 150 is indicated and is described in more detail in conjunction with FIG. 1B, which is a block diagram of an MR system 100 and includes a slice 160 through the cross-section 150 of the MR scanner 150 as well as additional components of the MR system 100 and their connectivity. The slice 160 illustrates a top part of the magnet 102a and a bottom part of the magnet 102b, a top part of the gradient coil 104a and a bottom part of the gradient coil 104b, a top part of the RF coil 106a and a bottom part of the RF coil 106b.

In addition, slice 160 shows a top part of transmit/receive coils 110a and a bottom part of transmit/receive coils 110b. These transmit/receive coils can surround a subject 112 (e.g., a human head) or can be placed above or below the subject or can be placed above and below the subject. The transmit/receive coils 110a and 110b and the subject 112 are placed within the magnet bore 108. The transmit/receive coils can have only a transmit functionality, only a receive functionality, or both transmit and receive functionalities. For example, a close-fitting smaller receive coil paired with a larger transmit coil can improve image quality if a small region is being imaged. Various types of coils (e.g., a head coil, a birdcage coil, a transverse electromagnetic or TEM coil, a set of array coils) can be placed around specific parts of a body (e.g., the head, knee, wrist) or can be implemented internally depending on the subject and imaging applications.

In FIG. 1B, the bottom part of transmit/receive coils 110b is connected to signal processor 114, which can include, e.g., pre-amplifiers, quadrature demodulators, analog-to-digital converters. Alternatively, the top part of transmit/receive coils 110a can be connected to signal processor 114. The signal processor 114 is connected to a computer 116. A systems controller 118, which is also connected to the computer 116, can include, e.g., digital-to-analog converters, gradient and RF power systems, power amplifiers, and eddy current compensation. The systems controller 118 is connected to the top part of the gradient coil 104a, the top part of transmit/receive coils 110a, and the bottom part of the RF coil 104b. Alternatively, the systems controller 118 can be connected to the bottom part of gradient coil 104b, the bottom part of transmit/receive coils 110b, or the top part of RF coil 104a.

The computer 116 controls the operation of other components of the MR system 100 (e.g., the gradient coil 106 and the RF coil 104) and receives MR data. In some embodiments, the computer 116 processes data associated with detected MR signals by executing operations, functions, and the like. The results of this data processing can be stored in memory 120, which can be random access memory (RAM), dynamic RAM (DRAM), static RAM (SRAM), etc. In some implementations, the memory 120 can include one or more storage devices (e.g., hard drives), individually or in combination with memory, for storing measurement data, processes, and other types of information.

In some embodiments, the computer 116 executes operations associated with a pulse sequence 122, and a calculator 124. The pulse sequence 122 is a set of instructions that are executed by various components of the MR system 100. The pulse sequence, which can reside in the memory 120, manages the timing of transmitted radiofrequency and gradient pulses as well as the collection of data.

The calculator 124, which can reside in the memory 120 and can be executable by the computer 116, performs operations (e.g., phasing, filtering, integrating, fitting, regressing) on the data collected from the MR system 100.

Techniques as disclosed in this specification can be implemented using the MR system 100, which can be any one of various commercial MR systems provided by, for example, Bruker BioSpin (Billerica, Mass.), Siemens Medical Solutions (Malvern, Pa.), or GE Healthcare Technologies (Milwaukee, Wis.), Philips Healthcare (Andover, Mass.).

### Image Processing for Volumetric Analysis

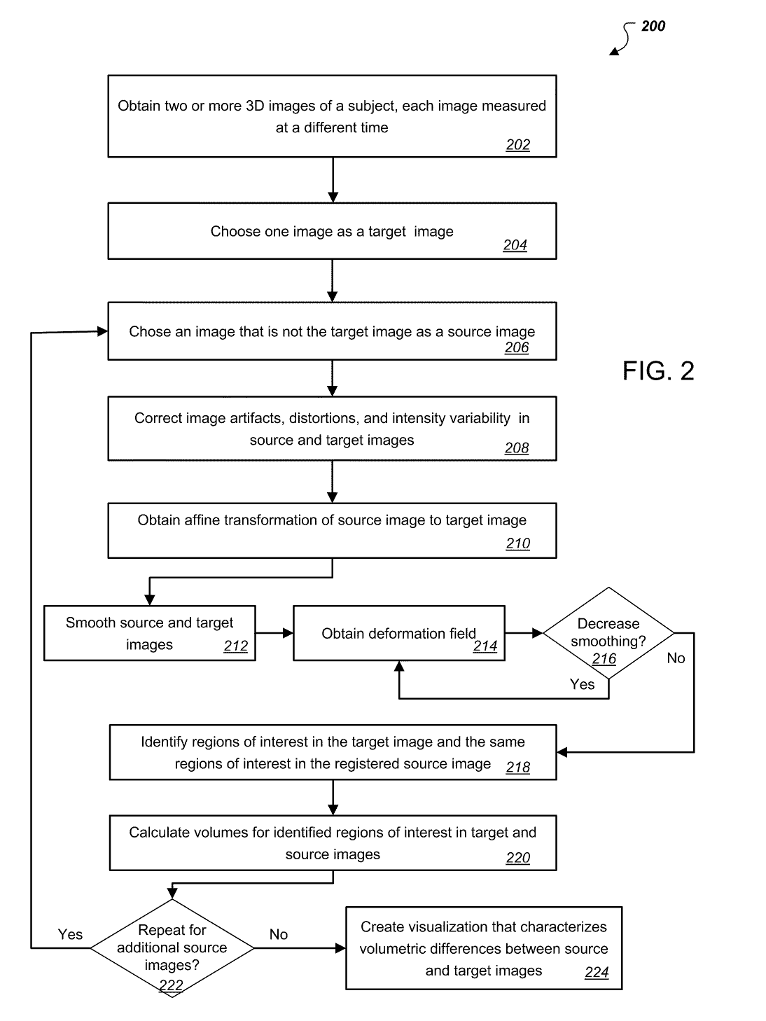

The process described in flowchart 200 in FIG. 2 relies on linear elasticity to find a deformation field that transforms structures (e.g., brain regions) within one image (e.g., an MRI scan) to the same structures within a different image (e.g., a later follow-up MRI scan). Linear elasticity is a mathematical study of solid object deformation under prescribed loading conditions and assumes that deformations are small, that components of stress and strain have linear relationships, and that stresses are small enough to always result in an elastic—and not a plastic—deformation of objects. Notably, local deformations and local volume changes can be obtained to find out in detail the changes taking place in whole regions or, with even greater detail, within a region of interest.

Referring to flowchart 200, two or more three-dimensional (3D) images (e.g., MR images, computed tomography images, positron emission tomography images, or other images) of a subject are obtained (202), in which each image is measured at a different time. For example, a first MR image (or a set of images that can be averaged) of a region of a subject can be taken at a first time and another MR image (or a set of images that can be averaged) of the same region of the same subject can be taken at a different time. Additional images can be obtained at other times, thus creating a longitudinal series of images of the region of the subject over a period of time.

One of the obtained images (e.g., the first image) is chosen (204) as the “target image” and another MR image is chosen (206) as the “source image.” Image artifacts (e.g., aliasing, motion artifacts), distortions (e.g., caused by gradient warping), and intensity variability between the target and source images are corrected (208). More details on these corrections are provided in the following sections.

An affine transformation is obtained (210) that registers or transforms the source image to the target image. For example, a cost function that represents a mapping error between the source and target images can have many parameters (e.g., translations, rotations, uniaxial strains and shears) and can be minimized simultaneously (e.g., by using a conjugate-gradients minimization). More details on registration methods are provided in the following sections.

Both the source and target images are smoothed (212) (e.g., by convolving with an isotropic Gaussian kernel of a given standard deviation). A deformation field is obtained (214) (e.g., by minimizing a cost function or mapping error that can include terms representing gradients of the displacements along each dimension at each voxel of the source image, amplitudes of the displacements, a quality of the registration, or other quantities).

The level of smoothing can be decreased (216) and a new deformation field can be obtained (214) that corresponds to the decreased smoothing. Iterating over decreasing levels of blurring permits the displacement field to gradually accumulate larger displacements.

Once a deformation field is obtained for a desired smoothing, regions of interest (ROIs) are identified (218) in the target image and the same ROIs are also identified in the registered source image. For example, an automated segmentation technique or a manual segmentation can be performed that divides the image of the sample into ROIs. Volumes are calculated (220) for the identified ROIs in both the target and source images.

Optionally, steps 206 through 220 can be repeated (222) for additional source images. If there are no more source images to analyze, a visualization can be created (224) that characterizes volumetric differences between the source and target images.

Although the steps in flowchart 200 are presented in one order, some steps can be omitted or can be performed in different orders.

### Unwarping Images

Before registering the images in any way, it is helpful to correct for deformation artifacts (e.g., artifacts resulting from nonlinearities in the space-encoding gradient magnetic field in the scanner) (see, e.g., Wald, L., et al., “Systematic spatial distortion in MRI due to gradient nonlinearities.” NeuroImage 13, S5). These distortions can be significant and one example correction method is based on a spherical harmonic description of the gradient magnetic field that requires vendor-supplied coefficients (see, e.g., Jovicich, J., et al., “Reliability in multi-site structural MRI studies: Effects of gradient non-linearity correction on phantom and human data.” NeuroImage 30, 436-443, April, 2006). This correction can be used, for example, as part of step 208, correcting image artifacts and distortions.

Any remaining distortions in structural images are typically affine. All images (e.g., images of the brain, knee, liver, heart, abdomen, or other organ) at subsequent times can be affine registered to the first image of the same region of the same subject. In some examples, each image can be a result of averaging a number (e.g., two, three, five, 10, or more) of images. To create an average of multiple images, a mask that defines the imaged region (e.g., the brain, knee, liver, heart, abdomen, or other organ) is needed. For example, if two images of the brain of a subject are obtained, a mask of the brain for the first image of the first pair is needed. This is because the full image (e.g., an MR image) will include brain stem, neck, shoulders, scalp, and eyes—all of which can change significantly from image to image, degrading the registration of more subtle brain changes.

Restricting affine registration to the brain allows for very good registration between the sequential images in the absence of other changes. The second image of the first pair can be rigidly registered to the first image, for example, by using sinc interpolation to resample (see, e.g., Kajnal, J., et al., “A registration and interpolation procedure for subvoxel matching of serially acquired MR images.” J Comput Assist Tomo 12, 289-296, March/April 1995). The voxel intensities can then be averaged.

To generate the mask, the first image can be mapped to an atlas or template that has a brain mask defined; the geometric mapping can be determined, for example, by minimizing the residual squared difference between the image and the template, in which the nonlinear warps can be parameterized with the lowest-frequency components of the three-dimensional discrete cosine transformation (see, e.g., Ashburner, J. and Friston, K. “Nonlinear spatial normalization using basis functions,” Kum Brain Mapp 7, 254-266, 1999; Frackowiak, R., et al., (eds.), Human Brain Function, 2nd Edn. Elsevier Academic Press, Amsterdam; “Spatial Normalization Using Basis Functions,” 655-672, 2004).

The mapping is invertible, and so the brain mask for the first image can be calculated. A similar but more accurate mask, based on automatic segmentation, can be used for the nonlinear registration which represents a mapping between two images that uses nonlinear operations. In some examples, the mask can end on the skull and include the brain stem down to where it starts to bend with the neck. In some examples, less precise masks can be used to achieve similar results from an affine registration.

The first time point average image can be written out in a 256³ voxel cube, in which each voxel is a 1 mm³ cube. The image intensities can be globally rescaled by bringing the cumulative probability distribution of brain voxel intensities into close agreement with that of a standard, for example, in which cerebrospinal fluid (CSF) has an intensity of about 25 and white matter has an intensity of about 150. This result can be used for the baseline image at time point 1 (TP1).

Using the same methodology, images at subsequent time points can be corrected (e.g., step 208), e.g., unwarped, intensity-averaged, standardized, and brought into affine agreement with the baseline image. The resulting images are now ready to be nonlinearly registered to the baseline image.

Robust and precise 6-parameter rigid and 12-parameter affine registration is an important factor in averaging images to reduce noise and to enable accurate nonlinear registration (e.g., performed in step 214) over time. A brief discussion follows on ways this can be accomplished.

### Affine Registration

Affine registration (step 210) can start with an initially coarse search through decreasing scales of translations and rotations to increasingly build up an accurate rigid registration of a source image to a target. The registration can start from the input orientations. At each orientation, a cost function c is evaluated:

$$c ( {α}_{1} , … , {α}_{6} ) = \frac{1}{N} {\sum }_{i = 1}^{N} {m}_{i} [ {S ( L ( {α}^{->} ) \cdot {{r}^{->}}_{i} - T ( {{r}^{->}}_{i} ) ]}^{2} , \qquad ( 1 )$$

in which N is the number of voxels, rᵢ is the location of the center of voxel i, whose intensity in the source image is denoted by S(rᵢ), and in the target image is denoted T(rᵢ), α₁ . . . α₆ are the translation and rotation parameters, with L(a) the current estimate of the rigid body transformation operator which acts on the spatial coordinates of voxels in S, and mᵢ is the target brain mask value for voxel i (equal to 1 inside the skull, ideally tapering to 0 at the skull and inferior to the brain). The value of this cost function represents the goodness of the source-to-target registration.

The sum need not be carried out over every voxel and can be, for example, carried out over every second or even fourth voxel along each dimension. Note that L can be written succinctly as a 4×4 matrix with the 3D position vectors written as 4-vectors whose last component is 1 (see, e.g., Ashburner et al., “Incorporating prior knowledge into image registration,” Neuroimage 6, 344-352, 1997; Frackowiak, R., et al., (eds.), Human Brain Function, 2nd Edn. Elsevier Academic Press, Amsterdam; Rigid Body Registration, pp. 635-653, 2004).

For any choice of α, if L reduces the cost c and thus improves the source-target registration, it is kept. Additional shifts along and rotations about the axes can be made sequentially by forming the product of L with the corresponding new shift/rotation matrix, giving a new L. If any shift or rotation reduces the cost further, the new L is accepted, and so on. This iterative process can be carried on down to any desired degree of accuracy. However, at the finer scales, the registration alternatively can be finessed by using a conjugate-gradients (CG) minimization over the {αₙ}. A slight blurring of the images can reduce the effects of noise. CG or similar schemes should not be used at the start because, in general, the images can be initially so far out of register that they do not have much of a chance of finding the global minimum.

With multi-scale searching and finessing, a precise minimum can be reached in a short time (e.g., a couple of minutes, about a minute, or under a minute). Having performed a multi-scale rigid registration, a full affine registration can be done using, for example, CG to simultaneously minimize a similar cost function with respect to a 12-parameter L that can include translations, rotations, uniaxial strains and shears.

### Local Intensity Normalization

Images can contain variations in intensity or brightness that result from factors other than the subject's underlying anatomy. For example, intensity variations in MR images can be caused by the subject's magnetic susceptibility or RF-field (B1) inhomogeneities. A first brain image can be too bright in the front of the head and too dark in the back, with the reverse situation for other brain images. If uncorrected, this can result in a calculated expansion or contraction that is inaccurate.

When nonlinearly registering image A to image B (e.g., as part of step 214, obtaining a deformation field), which have already been affine registered, heavily smooth both (e.g., convolve with a Gaussian kernel with a standard deviation of about 20 voxels). This will result in intensities aᵢ and bᵢ at voxel i in smoothed images A and B, respectively. For each voxel in B, scale its intensity by aᵢ/bᵢ, producing B′. This can give very accurate local intensity agreement between the images in the absence of relative deformations. The above techniques can be used, e.g., as part of step 208 (correcting intensity variability in source and target images).

When there is a large internal relative displacement between the images involving high contrast, which can occur when the lateral ventricles expand or contract, this procedure can incorrectly scale intensities in the displaced region. This can be rectified in a self-consistent manner with the help of the nonlinear registration: locally scale the intensities as described, perform a nonlinear registration, apply the displacement field to A to produce A′, locally rescale B with respect to A′ as before, producing a new B′. This can be repeated for multiple nonlinear relaxation steps (e.g., two, three, five, eight, 10 or more steps), after which, A and the final B′ will have consistent intensities. As the number of nonlinear registration steps increases, the smoothing kernel size slowly can be decreased (e.g., from a standard deviation of about 20 voxels to about 15, 12, 10, eight, five, or fewer voxels). Intensity normalization should be conducted conservatively, because the aim is to correct for intensity changes between a serial pair of scans that are purely scanner artifacts, and not otherwise alter the images.

For example, an imaged scalp of a subject can change substantially over a series images obtained within six months. Even foam blocks that are pressed on the scalp to help keep the head in a fixed position in the scanner can alter the shape of a scalp. As such, the normalization method just described may be less accurate in brain regions near the skull, because normalization based on images smoothed with wide Gaussian kernels can be affected non-locally. More generally, this Gaussian method of normalization implicitly assumes a spherical symmetry in relative intensity nonuniformity around any voxel, a situation that only arises in regions in which the intensity difference is indeed uniform. In regions of variation in the intensity difference itself, this is no longer the case.

Assuming only that a relative intensity variation between a pair of images is spatially smooth, a more accurate map of it can be made by minimizing a cost function of the form

$$f ( {b}_{1} , … , {b}_{6} ) = \frac{1}{N} {\sum }_{i = 1}^{N} {m}_{i} \{ {[ {b}_{i} S ( {{r}^{->}}_{i} ) - T ( {{r}^{->}}_{i} ) ]}^{2} + {γ}_{1} {b}_{i}^{2} + {{γ}_{2} ( {∇}^{->} {b}_{i} )}^{2} \} , \qquad ( 2 )$$

in which bᵢ is the intensity scaling factor at voxel i in image S that makes the intensity at that location closely agree with the intensity at voxel i in registered image T; γ₁ and γ₂ are regularization parameters. Because intensity nonuniformity varies only very gently across images, this procedure can be very precise and robust. Intensity normalization and structural registration should be run iteratively until convergence is reached, as one method helps the other.

Optimal γ₁ and γ₂ can be found by numerically exploring the impact of each on intensity normalization for images that appear geometrically almost identical and suffer from intensity distortion. Note that the smoothness of the intensity variation means that the sum in equation 2 need not be carried out over all voxels—every second voxel can produce accurate results.

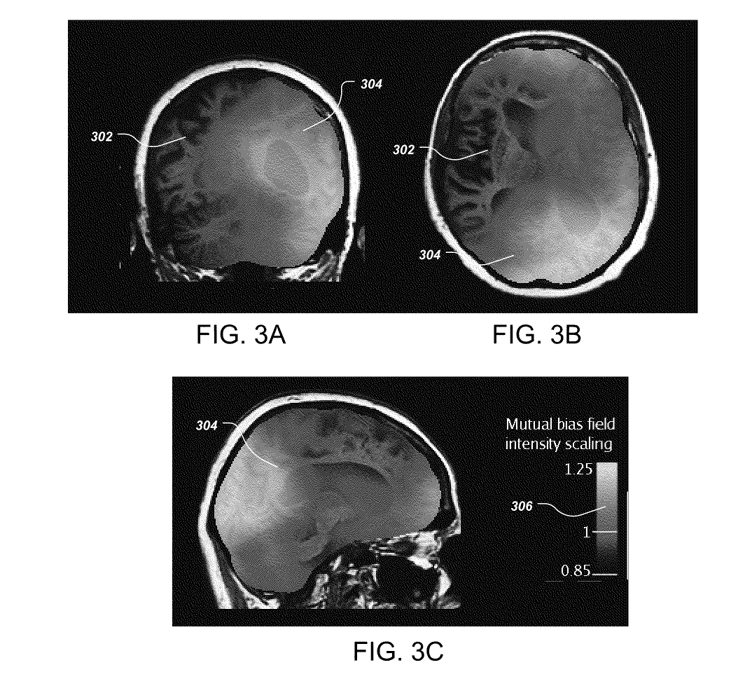

Referring to FIGS. 3A-C, a two-year follow up scan 302 is shown with a color overlay 304 of a mutual bias field correction. A scale 306 for the bias field correction is shown in FIG. 3C. A local intensity scaling of the two-year follow-up image was required to make anatomically-identical points in it and the baseline image have similar intensities. The opacity of the intensity scaling field, as shown by color overlay 304, is reduced to show brain structures in scan 302 underneath.

### Nonlinear Registration and Selection of Cost Function

Nonlinear registration involves finding individual three-dimensional displacements at each voxel that map the source image to the target. This can also be carried out by minimizing a cost function, the value of which represents a mapping error between the source and target images. In this case, the cost function depends not on 6 or 12 variables but on 3N, in which N is the total number of voxels. A suitable cost function and an efficient minimization scheme can be provided. The reasoning behind a cost function can be understood in terms of Bayesian statistics, Gibbs potentials, and expectation values (see, e.g., Frackowiak, R. et al., (eds), Human Brain Function, 2nd Edn. Elsevier Academic Press, Amsterdam; High-Dimensional Image Warping, 673-694, 2004). It can also be understood directly. A relatively simple and effective cost function will have a quadratic driving term of intensity differences, similar to equation 1, which vanishes when the correct displacements have been found:

$$f ( {{u}^{->}}_{1} , … , {{u}^{->}}_{N} ) = \frac{1}{N} {\sum }_{i = 1}^{N} {{m}_{i} [ S ( {{r}^{->}}_{i} + {{u}^{->}}_{i} ) - T ( {{r}^{->}}_{i} ) ]}^{2} , \qquad ( 3 )$$

It is assumed here that the images S and T have been affine aligned and spatially normalized. The vector uᵢ=(uᵢₓ, u_{iy}, u_{iz}) is the displacement at voxel i such that at the correct local registration, the resampled image S′ will look practically identical to T, where S′(rᵢ)≡S(rᵢ+uᵢ). The sum now involves all voxels; taking only every second voxel, say, allows only a relatively crude registration. The system can be constrained and regularized (see, e.g., Frackowiak et al., (eds.), Human Brain Function, 2nd Ed., Elsevier Academic Press, Amsterdam; High-Dimensional Image Warping, 673-694 (2004), to preserve topology and keep the deformation field u(r)≡{uᵢ} smooth. Topologically distinct images, for example, in which one image has a tumor and the other does not, are more complicated (see, e.g., Studholme et al., “Deformation-based mapping of volume change from serial brain MRI in the presence of local tissue contrast change,” IEEE Trans Med Imaging 25, 626-639, 2006). However, most of the pathologies we are exploring involve deformations (e.g., expansion, growth, compression, atrophy, displacement) that are continuous on the image scales (e.g., about 1 mm).

A smooth deformation field can be obtained by controlling the sum of the squares of the gradients of the displacements along each dimension at each voxel. A term can also be added constraining the amplitude of the displacements. Hence, including the driving term that appears in equation 3, a suitable cost function f is

$$f ( {{u}^{->}}_{1} , … , {{u}^{->}}_{N} ) = \frac{1}{N} {\sum }_{i = 1}^{N} {m}_{i} \{ \begin{matrix}{[ S ( {{r}^{->}}_{i} + {{u}^{->}}_{i} ) - T ( {{r}^{->}}_{i} ) ]}^{2} + \\ {λ}_{1} {dr}_{i}^{2} + {λ}_{2} [ \begin{matrix}{( {∇}^{->} {{u}^{->}}_{ix} )}^{2} + \\ {( {∇}^{->} {{u}^{->}}_{iy} )}^{2} + \\ {( {∇}^{->} {{u}^{->}}_{iz} )}^{2}\end{matrix} ]\end{matrix} \} , \qquad ( 4 )$$

in which λ₁ and λ₂ are regularization parameters of the model that control the quality of the registration. These regularization parameters can have a range of valid values (e.g., 0-3000, 500, 1000, 1500, or higher), but that range depends on the scale of intensities. In some examples, standardized images are used and parameters of λ₁=0 and λ₂=1500 can be used.

There can be variations on this cost function. For example, higher powers could be used; the smoothing gradient term could have been from a divergence |∇·uᵢ|², thus including cross terms, or neighboring displacements can be explicitly included to prevent sawtooth or corrugated displacements, e.g., [(uᵢₚₓ−uᵢₓ)²+(uᵢₓ−uᵢₘₓ)²], in which “ipx” denotes the voxel on the +x-side of voxel i and “imx” denotes the voxel on the −x-side of voxel i, with similar terms for y and z; the cross-correlation of the images can be included; ln(|Jᵢ|) can be included, in which Ji is the Jacobian of u(r) at rᵢ and provides the advantage of being the same when mapping volume element dV_{S} to dV_{T} or the reverse, so that each is equally likely to result from the other (see, e.g., Frackowiak et al., (eds.), Human Brain Function, 2nd Edn. Elsevier Academic Press, Amsterdam; High-Dimensional Image Warping, 673-694, 2004).

Given an image at time point 1 (TP1) and a series of followup scans, e.g., at time point 2 (TP2), time point 3 (TP3), and so on, it is desirable to know how particular regions defined in TP1 change over time. This requires knowing the displacement fields in TP1-space. Registering TP2 to TP1 (in equation 3, S would be the TP2 image and T the TP1 image) produces the field {uᵢ} written out in TP1-space, which allows S to be resampled in TP1-space. {uᵢ} specifies where to locate voxel centers in the TP2 image, in general turning cubic voxels into displaced irregular hexahedra. Given the corners of a hexahedron, which can be determined by trilinear interpolation of the displacements at the voxel centers, a volume can be calculated in several ways (see, e.g., Garg, V., Applied Computational Fluid Dynamics, Marcel Dekker, Inc., New York, Ch. 2. Numerical Techniques, 1998; Davies, D. and Salmond, D., “Calculation of the volume of a general hexahedron for flow predictions,” AIAA J 23, 954-956, 1985; Grandy, J., “Efficient computation of volume of hexahedral cells,” Informal report UCRL-ID-128886, Lawrence Livermore National Laboratory, 1997). For example, the volume of a hexahedron can be given by one-sixth the sum of three determinants of 3×3 matrices built from the coordinates of the vertices.

The calculated deformation or displacement field indicates how to locate the eight corner points of the hexahedral volume element in TP2 that correspond to the corners of a particular cubic voxel, (e.g., voxel index i in TP1). Starting from standardized images in which all voxels are 1 mm³, a hexahedral element of volume<1 implies that the hexahedron expanded into the 1 mm³ voxel in TP1. Similarly, a hexahedral volume>1 implies that the hexahedron has contracted to 1 mm³ in TP1.

### ROI Volume

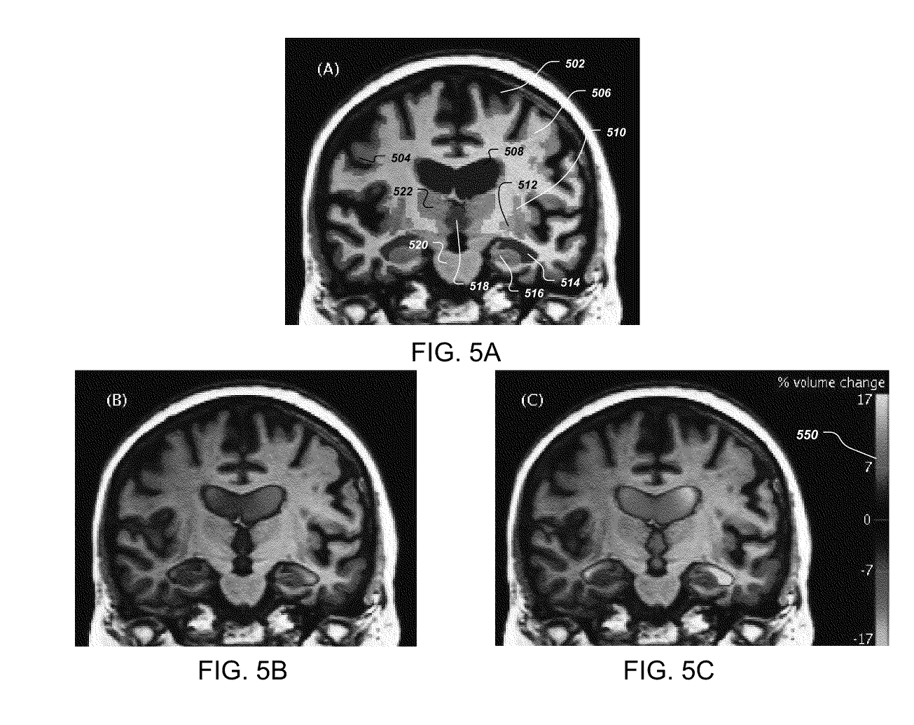

Regions of interest can be specified (e.g., as in step 218) by manual segmentation or by automated segmentation (see, e.g., Fischl et al., “Whole brain segmentation: Automated labeling of neuroanatomical structures in the human brain,” Neuron 33, 341-355, 2002). In some example, automated segmentation defines voxels as either fully in or not in a particular anatomical ROI-automatic segmentation ROI boundaries do not traverse voxels. FIG. 5A (discussed in Example 2) displays a brain image that has been automatically segmented into multiple ROIs.

The volume change for a whole anatomical ROI can be obtained by averaging the volume changes for all the voxels identified as in the ROI, ignoring a thin layer (e.g., about a voxel thick) on the boundary. This extra layer can account for voxels being wholly misidentified or for voxels that inevitably will straddle tissue boundaries.

Because the deformation field is designed to be uniform over the ROI, averaging over the interior of the ROI can be reasonable, especially when the ROI interior is large.

### ROI-specific Nonlinear Registration

Small volume changes in nestled regions of interest, e.g., a hippocampus in the temporal horn of a lateral ventricle, might not register precisely, particularly when image blurring is not taken all the way to zero blurring in the course of nonlinear registration. The problem is potentially two-fold: insufficient degrees of freedom for the deformation field to separate boundaries or ROIs, and smallness of scale. In the extreme case, a voxel can be pulled in opposite directions, but this movement is represented by a single displacement vector.

One solution is to expand the ROI to fill a larger volume of voxels, increasing the number of voxels by a factor of at least 2 along each dimension. An accurate nonlinear registration can now be done, and the displacement field can be scaled back at the end.

In this manner, many more degrees of freedom can be used when finding displacement vectors, where otherwise there may only be a voxel or two separating it from neighboring regions. This method can be applied to any region in turn. Volume changes on the order of a percent can be measured.

Using manual or automatic segmentation this method can be applied to any ROI of any subject. This method can be combined with multiple relaxation steps for very precise registration. Finally, the whole brain can be inflated as an ROI and nonlinearly registered with multiple relaxation steps, simultaneously providing greater precision for the cortical surface and all sub-cortical ROIs. In some examples, doubling the degrees of freedom along each dimension for the whole brain can be implemented. In some examples, ROIs can be combined (e.g., the amygdala, lateral ventricle of the temporal horn, and hippocampus can be treated as a single ROI) and the resulting single ROI can be inflated and registered. In some examples, bilateral structures can be registered independently for each side.

Because the displacement field can, by design, be fairly smooth over regions of homogeneous contrast, finding the ROI volume change can be made robust to imperfections in the segmentation scheme by choosing a conservative (e.g., eroded) mask for the ROI. Patterns of ROI deformation (e.g., across the whole brain) can be investigated across subjects, over time, and for various pathologies to define pathology-specific trajectories. Example pathologies can include neurodegenerative disorders, cancer, inflammatory diseases, immunologic diseases, or other neurodegeneration.

### Extension of Methods to Multi-Modal Image Registration

When the contrasts of the images being registered are different, e.g., different MRI modalities (e.g., T1-weighting, T2-weighting, proton density weighting, fractional isotropy, magnetization transfer, contrast-agent enhanced, two field strengths, two pulse sequences) or MRI-PET, the cost function can be generalized to incorporate mutual information, i.e., the relationships between the ROI image intensities in both modalities (see, e.g., Leventon, M., et al., “Multi-modal volume registration using joint intensity distributions,” In Proc. MICCAI'98. Springer, 1057-1066, 1998). In such cases, it will be necessary to minimize a cost function in which the driving (image difference) term is the negative of the natural logarithm of the joint probability of the images:

$$f \sim ln P ( S , T \vert U , \{ {β}_{k} \} ) = - {\sum }_{i} ln P ( S ( {{r}^{->}}_{i} + {{u}^{->}}_{i} ) , T ( {{r}_{i}}^{->} ) \vert \{ {{u}^{->}}_{i} \} , \{ {β}_{k} ( i ) \} ) , \qquad ( 5 )$$

in which βₖ(i) will specify how the intensity in image T at voxel i needs to be scaled to make the modalities agree, based on the probability that it is tissue type k. The regularization of the new cost function and the method of minimization can be similar to those outlined for same-modality registration; βₖ will also need to be regularized.

### Nonlinear Registration by Multiple Relaxation Steps

The gradient term in the cost function can keep displacements shorter than they should be, for example, if there is a tissue boundary between regions undergoing different rates of volume change. The effect can be small and results as a trade-off with respect to the smoothness (stiffness) of the displacement field.

The degree of under-registration depends on the direction of the mapping (e.g., source to target or target to source), because the regularization term in equation 4 is not symmetric with respect to forward and inverse mappings. Therefore, at any particular tissue boundary, the quality of the registration will, in general, not be the same for forward and reverse registrations, depending on the relative geometries and volumes of the adjacent regions undergoing expansion and contraction.

For example, suppose that in a follow-up scan at time point 2 (TP2), the left and right lateral ventricles have expanded and the surrounding much larger white matter has contracted, relative to their sizes at time point 1 (TP1). From elementary properties of elastic media, the TP1→TP2 mapping should produce a slightly better registration (the TP1 image resampled in TP2-space) than the TP2→TP1 mapping (the TP2 image resampled in TP1-space).

To correct for under-registration requires an extra one or more (e.g., one, two, five, or more) nonlinear registration steps. In some examples, in the first step, as described above, a displacement field can be calculated for the image undergoing nonlinear transformation. The image can be updated (e.g., resampled using the calculated displacement field), and the resultant image can be nonlinearly registered to the same target. This procedure can be repeated for another few steps, with the displacement field at later steps rapidly becoming vanishingly small. Finally, the displacement fields for all the steps can be retraced to calculate the net displacement field.

For a fixed λ₂, increasing the number of nonlinear registration steps is equivalent to a single nonlinear registration step with a smaller λ₂, though without the numerical instability that can occur for displacements involving high contrast change, where the driving term (equation 3) overpowers the regularization term. Also, a larger λ₂ will produce a more uniform deformation field within an ROI.

It is preferable to maintain as uniform a displacement field as possible within each ROI, while still effecting as accurate a registration as possible, so as to allow for a robust estimate of the volume change within each ROI, i.e., so that the volume change calculation is not overly sensitive to the precise alignment of the automatic segmentation-generated ROI mask with the tissue boundary. In some examples, two or three TP2→TP1 nonlinear registration steps can be adequate to produce a precise registration with a uniform displacement field.

This method leads to very tight registration, but can be sensitive to imperfections in the data and tissue contrast changes. Therefore, correction of data imperfections and tissue contrast changes between images (e.g., as described in step 208 of flowchart 200) is important. For example, local intensity normalization (described in a previous section) is important for accuracy and can be run in tandem with a series of nonlinear registration steps.

### Minimization of Cost Function

The images being locally registered can be already tightly affine registered, and if each is heavily smoothed, e.g., by convolving with an isotropic Gaussian kernel of standard deviation of about 4-5 mm, they can appear rather similar, even though the unsmoothed images may have relative internal deformations on the order of about a cm. This can be exploited to get around the myriad local minima on the path toward the global minimum of function f. In other words, given a current estimate of {ui}, which can be initialized to all zeros, sufficient smoothing can allow the global minimum location to be accessible, if not visible, unobstructed by local hills and troughs in a landscape of 3N-dimensions. Having reached that point, one has a very good estimate for the new global minimum at a finer level of smoothing. Iterating over decreasing levels of blurring allows the displacement field gradually to accumulate large displacements.

It is advantageous not to go to zero blurring—otherwise the deformation field may not be smooth as a result of sensitivity to noise, minor motion artifacts or other, non-corrected imperfections in the data, or to contrast changes that cannot reasonably be interpreted as volumetric changes. A tight registration and a smooth deformation field effecting that registration are desired, from which a smooth volume-change field can be calculated and averaged over ROIs. Also, minimizing the deformation field with zero blurring can be difficult to control numerically.

The minimization carried out at any level of image smoothing can be done most expeditiously if as much gradient information as possible is taken into account, for example, using conjugate directions in a second-order Newton's method (see, e.g., Gershenfeld, N., The Nature of mathematical Modeling, Cambridge University Press, 1999). Other methods include steepest descent, in which only the steepest gradient direction is used, requiring the next step to be orthogonal. The high smoothing and overall similarity of the images means a second-order Taylor expansion of f can be a reasonable approximation, as with enough smoothing can result in a concave basin of attraction. So the quadratic form approximation for f can be perturbed around the current best estimate U=(uᵢₓ, u_{iy}, u_{iz}, u₂ₓ, . . . , u_{Nz}) of the system displacement vector, producing a large, sparse, symmetric linear algebra problem:

H(\vec{U})·V=−\vec{G}(\vec{U}), (6)

in which H(U) is the Hessian of f at U, G(U) is the gradient of f at U, and the unknown quantity V=(v₁ₓ, v_{1y}, v_{1z}, v₂ₓ, . . . v_{Nz}) is the displacement around U that nudges f toward the new global minimum U+V at the new (finer) level of smoothing. The sparseness results from the coupling only of neighboring voxels through the derivative terms in H. There exist several efficient iterative methods for finding the solution V of equation 6, e.g., conjugate gradients squared (CGS), generalized minimal residuals (GMRES), and biconjugate gradients stabilized method (Bi-CGSTAB) (see, e.g., van der Vorst, H., Iterative Krylov Methods for Large Linear Systems, Cambridge University Press, Cambridge, 2003). The cumulative minimization thus carried out over a series of images of decreasing smoothness constitutes a single nonlinear registration step.

Embodiments of the processing techniques described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a tangible program carrier for execution by, or to control the operation of, data processing apparatus. The tangible program carrier can be a propagated signal or a computer readable medium. The propagated signal is an artificially generated signal, e.g., a machine-generated electrical, optical, or electromagnetic signal, that is generated to encode information for transmission to suitable receiver apparatus for execution by a computer. The computer readable medium can be a machine-readable storage device, a machine-readable storage substrate, a memory device, a composition of matter effecting a machine-readable propagated signal, or a combination of one or more of them.

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, or declarative or procedural languages, and it can be deployed in any form, including as a stand alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, input from the user can be received in any form, including acoustic, speech, or tactile input.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described is this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

Appendix 2 of U.S. provisional application 60/988,014 is entitled “FAST CORRECTION OF IMAGE DISTORTIONS BY INHOMOGENEOUS MAGNETIC FIELDS IN MAGNETIC RESONANCE IMAGING” and provides additional technical information for the systems and techniques described in this application and is part of this application. The methods and systems described in Appendix 2 can be taken alone or in combination with the methods described elsewhere in this application.

### EXAMPLES

The present techniques can be used to calculate very fine changes in volume between two time points when a sequential images (e.g., MR images) of a subject have been obtained. The changes can be graphically displayed in a color-coded way that immediately reveals to the naked eye what changes are taking place within the subject. Not only can these techniques and systems present the global picture of change within a subject (e.g., the whole brain of a subject), but they can also focus on any specific region of interest, e.g., hippocampus, and with greater finesse, accurately calculate the volumetric change there, and even the displacements and distribution of change within the region of interest. This has clear clinical and diagnostic application: what is the pathology; what is the extent of the pathology; how is the subject responding to possible drug treatment over time; detecting nascent tumors; response of tumors to radiation, chemotherapy, or both.

### Example 1

### Model Studies

To test the accuracy and robustness of the described registration method, it was applied to models of two relatively extreme situations that are likely to arise in the context of brain registration: (A) large regions undergoing large volume change, e.g., ventricular expansion and contraction, and (B) small nestled regions involving several subregions of distinct intensities undergoing small volume changes, e.g., a hippocampus on white matter in the temporal horn of a lateral ventricle.

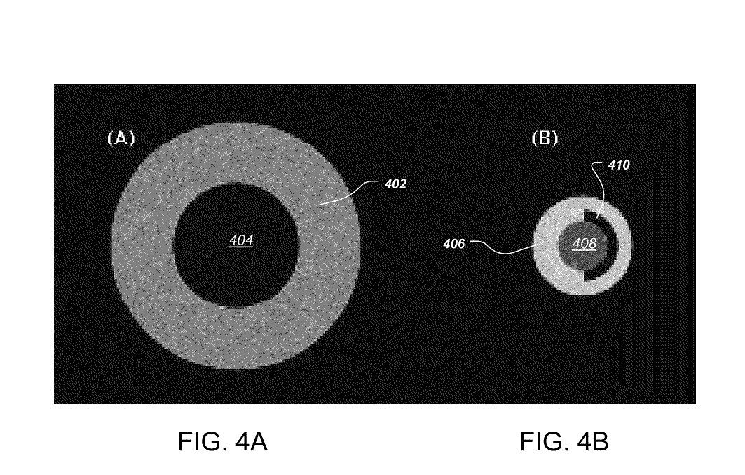

Referring to FIGS. 4A-B, nested spheres of different intensities were used to test both of these cases. The natural length unit in these studies is the length of a side of a cubic voxel, vl; in the neuroanatomies considered below, a voxel is cubic and of length 1 mm. The scale used for the models' intensities was set by the standardized images of the brains: CSF ˜25, hippocampus ˜100, white matter ˜150.

Rician noise (Gudbjartsson, H., and Patz, S., “The rician distribution of noisy MRI data,” Magn Reson Med 34, 910-914. 1995; Pannalal, B., Modern Digital and Analog Communication Systems, 3rd Ed, Oxford University Press, New York, 520-521, 1998) was added to the intensities, the two Gaussian components of which had a standard deviation of 5, approximately corresponding to noise in the brain images.

Each model consists of a pair of volume images to be mutually registered. For model A, only one pair of images was studied. FIG. 4A shows a slice through the first of these images: the radius of an inner sphere 404 is 25 vl, and the radius of a larger sphere 402 is 50 vl. In a second, later image (not shown), the inner sphere was 30% larger (a radius increase of 2.28 vl) and the outer radius did not change. Noise intensities were distributed around mean intensity magnitudes of 25 for inner sphere 404 and 120 for outer sphere 402.

For model B, a series of image pairs was studied. FIG. 4B shows a slice through the first image for the first of the image pairs: the radius of an outer sphere 406 is 20 vl, the radius of an inner sphere 408 is 10 vl, the inner radius of a spherical shell 410 between the two spheres is 14 vl, and the outer radius of the spherical shell is 19 vl. The inner sphere 408 in the second image (not shown) is 5% smaller (a radius decrease of 0.17 vl); the radii of outer sphere 406 and spherical shell 408 remained fixed. Note that the spherical shell 408 includes two half-shells, one of which has the same intensity as the outer shell. Noisy intensities were distributed around mean intensity magnitudes of 150 for the outer sphere 406, 100 for the inner sphere 408, 150 for the outer shell of spherical shell 410, and 25 for the remainder of the spherical shell. The series of image pairs were similar except the inner radius of the outer shell of spherical shell 410 varied from 18 vl down to 11 vl. Table 1 lists volume changes for the inner sphere 408 based on values of the difference between the first value (R2) and second value (R1) for the inner radius of the outer shell of spherical shell 410.

For each configuration, simulations were performed on twenty pairs of images—unique noisy instantiations—and the volume of the interior expanding or contracting inner sphere 408 was calculated. Since the volume change for a brain ROI is calculated by averaging the volume changes of all the voxels in the ROI (as identified by automatic segmentation), this method was also used for the models. The issue is how to handle the boundary voxels, which may be partly outside the ROI. Since the deformation field that effects registration is fairly uniform over the ROI, one only needs to average over voxels that are fully within the ROI—and the more of these that are included the more correctly the volume change thus calculated will reflect the actual volume change induced by the deformation field. If a mask is built from voxels identified as belonging in whole or in part to the ROI, this should be shrunken slightly, and the ROI volume change averaged over voxels within the shrunken mask.

There will be slight variations in the estimated volume change, depending on the mask. More importantly, however, one can be consistent across ROIs by building the shrunken mask in a consistent way—e.g., by smoothing and thresholding a binary mask built from voxels identified as ROI tissue by automatic segmentation.

For model A, in which a 30% volume increase for the inner sphere is expected, a single nonlinear registration gives 27.8%, slightly underestimating the correct result: uniform expansion or contraction isn't penalized but nonuniform deformation is,

and this can happen near tissue boundaries. The gradient in the deformation field there effectively acts as a spring restricting
deformation, thus leading to an underestimate of the true displacement. This underestimate could be reduced by using a smaller spring constant (λ₂ in Eq. 3). However, a reduced spring constant means greater sensitivity to noise and other imperfections in the data, and so is not always desirable. A way around this limitation is to update the image undergoing transformation given the estimated deformation field, and then register the updated image to the original target—i.e., perform two relaxation steps.

The calculated volume increase for model A then is 29.7%. The standard deviation in both calculations is zero to one decimal place. For situations as in modelvB, the underestimation of the volume change is generally greater than in model A, and up to 5 relaxation steps may be needed to get the correct result, as can be seen in the rows of Table 1 in which R2-R1 is 8, 6, and 4 vl.

When only one voxel separates the structures, R2−R1=1 vl, relaxation alone will not suffice: the images must be zoomed, i.e., more degrees of freedom are needed, and then several relaxation steps performed. In the last three rows, note that zooming with only one relaxation step is already a significant improvement on one relaxation step with no zooming. The row R2−R1=4 vl shows that zooming is unnecessary when enough degrees of freedom are present, so that 5 relaxation steps with or without zooming gets the correct result.

TABLE 1
Mean (standard deviation) percent volume change for inner sphere

| | % vol | % vol | % vol | % vol | % vol | % vol | % vol |
|---|---|---|---|---|---|---|---|
| | change | change | change | change | change | change | change |
| R2-R1 | 1 relax | 2 relax | 5 relax | 1 relax | 2 relax | 5 relax | 10 relax |
| (vl) | step | steps | steps | step | steps | steps | steps |
| 8 | 3.0 (0.1) | 4.2 (0.2) | 5.3 (0.3) | 3.6 (0.1) | 4.7 (0.2) | 5.2 (0.2) | 5.2 (0.3) |
| 6 | 2.9 (0.2) | 4.2 (0.2) | 5.2 (0.3) | 3.5 (0.2) | 4.6 (0.2) | 5.1 (0.3) | 5.1 (0.3) |
| 4 | 2.8 (0.1) | 4.0 (0.2) | 5.2 (0.3) | 3.4 (0.1) | 4.6 (0.2) | 5.2 (0.2) | 5.2 (0.2) |
| 2 | 1.7 (0.1) | 2.7 (0.2) | 4.4 (0.3) | 3.0 (0.1) | 4.2 (0.2) | 5.1 (0.2) | 5.1 (0.2) |
| 1 | 0.9 (0.2) | 1.3 (0.2) | 1.4 (0.3) | 2.3 (0.1) | 3.4 (0.2) | 4.6 (0.3) | 5.1 (0.3) |

### Example 2

### Volumetric Changes in Subject Initially Diagnosed with Mild Cognitive Impairment (MCI)

Alzheimer's disease (AD), for example, is believed to be irreversible, so early diagnosis is important for therapeutic efforts aimed at slowing or halting its development to be successful. Progressive atrophy in AD arises from neuron and synapse loss and can be seen on structural MRI scans (Ramani, A., et al., “Quantitative MR imaging in Alzheimer Disease,” Radiology 241, 26-44, 2006). Currently, however, behavior monitoring and performance on standard neuropsychological tests are used as the primary means of diagnosing AD (McKhann, G., et al., “Clinical diagnosis of Alzheimer's Disease: Report of the NINCDS-ADRDA Work Group under the auspices of Department of Health and Human Services Task Force on Alzheimer's Disease,” Neurology 34(7), 939-44). By the time a positive diagnosis is made, significant cognitive impairment has already occurred and the neuronal damage may be extensive, particularly for those with high premorbid ability (Roe, C., et al., “Education and Alzheimer disease without dementia: support for the cognitive reserve hypothesis,” Neurology 68, 223-228, 2007).

This example monitors volumetric changes in patients diagnosed with a Mild Cognitive Impairment (MCI) over time. The measured longitudinal changes of MCI patients who are later diagnosed with AD are compared to those MCI patients who are not.

### Data Acquisition and Preparation

All subjects are scanned twice with a 3D MPRAGE protocol at 1.5T every six-months. Double scanning allows up to a √2 increase in signal-to-noise. At each time point, to provide a faithful geometric representation of the subject, reduce noise, and be in a position to consistently determine over time what parts of the brain are growing, shrinking, or merely being displaced, and by how much, several processing steps are required (e.g., steps in flowchart 200: image correction, obtaining a brain mask for the images, affine registration, intensity normalization, and non-linear registration).

All brain images at subsequent times will be affine registered to the average of the first pair of brain images using the brain mask for the first image of the first pair. To generate the mask, the first image is mapped to an atlas or template which has a brain mask defined; the geometric mapping is determined by minimizing the residual squared difference between the image and the template, where the nonlinear warps are parameterized with the lowest-frequency components of the three-dimensional discrete cosine transformation.

Restricting affine registration to the brain allows for essentially perfect registration in the absence of other changes. The second image of the first pair will be rigidly registered to the first image, using sinc interpolation to resample. The voxel intensities are then averaged.

The first time point average image is then written out in a 256³ voxel cube, where each voxel is a 1 mm³ cube. The intensities are then globally rescaled by bringing the cumulative probability distribution of brain voxel intensities into close agreement with that of a standard, where cerebrospinal fluid ˜25 and white matter ˜150. The result is the baseline image at time point 1 (TP1).

Using the same methodology, images at subsequent time points are unwarped, intensity averaged, standardized, and brought into affine agreement with the baseline image. The resulting images are now ready to be nonlinearly registered to the baseline image.

With the standardized images in this example, values of λ₁=0 and λ₂=1500 were used. Also, the amygdala, lateral ventricle of the temporal horn, and hippocampus were treated as a single ROI and inflated to fill a volume of 1803 voxels and registered (left and right independently).

All results presented here were obtained using Bi-CGSTAB. Data were obtained from the ADNI database (www.loni.ucla.edu/ADNI). ADNI is the result of efforts of many co-investigators from a broad range of academic institutions and private corporations. Subjects have been recruited from over 50 sites across the U.S. and Canada. ADNI's goal was to recruit 800 adults, ages 55 to 90, to participate in the research-approximately 200 cognitively normal individuals to be followed for 3 years, 400 people with MCI to be followed for 3 years, and 200 people with early AD to be followed for 2 years (see www.adni-info.org).

The research protocol was approved by each local institutional review board and written informed consent is obtained from each participant. Techniques have been applied to over a thousand pairs of scans in the Alzheimer's Disease Neuroimaging Initiative (ADNI) database. For ADNI subjects, all later time points were intensity normalized to the baseline image using this method, i.e., by registering TP1→TP2, TP1→TP3, etc., using up to eight relaxation steps. The later time points thus normalized were then directly be nonlinearly registered to the baseline image, using multiple (usually three) relaxation steps.

### Application to Subject Data

Nonlinear registration was performed on over 1000 pairs of serial scans from the ADNI database, with volume change calculated from the displacement fields. Example results for one subject are shown in FIGS. 5A-C and 6A-c. FIGS. 5A-C show the same baseline coronal slice for the subject, initially diagnosed as having mild cognitive impairment (MCI), overlain with (A) tissue segmentation, (B) percent volume change after six months, and (C) percent volume change after twelve months.

Referring to FIG. 5A, the coronal image of the subject has been segmented into many regions, such as cerebrospinal fluid 502, gray matter 504, white matter 506, lateral ventricles 508, putamen 510, pallidum 512, inferior lateral ventricle 514, hippocampus 516, third ventricle 518, cerebellum 520, and thalamus 522. Additional structures can also be segmented.

FIGS. 5B and C show volume changes within the subject by displaying a color overlay with a color key 550, in which red colors represent a percentage increase in volume and blue colors represent a percentage decrease in volume. For example, at six months, the region that represents the subject's left lateral ventricle 514 (subject's left is on the right of the brain image) has expanded by 10%; at twelve months it has expanded by 19%. Although not shown here, this subject also had follow-up scans at 18 and 24 months, for which the left lateral ventricle expanded by 24% and 31%, respectively.

At 6 months there is pronounced widening-up to 8% increase in volume of subarachnoid CSF 502 of the right lateral sulcus (which is part of gray matter 504). Note in particular the localized cortical gray matter 504 shrinkage, which was up to 8% at 6 months and 12% at 12 months, on the lateral and inferior temporal lobes. This was quite distinct from the adjacent and less pronounced shrinkage of white matter 506.

FIGS. 6A-C show the left-hemisphere baseline cortical surface of the same subject as in FIGS. 5A-C, overlain with (A) automatic ROI segmentation, (B) percent volume change at 6 months, and (C) percent volume change at 12 months.

Referring to FIG. 6A, various segmented regions of the subject's brain are shown. For example, pre-central gyrus 602, post-central gyrus 604, superior parietal lobe 606, inferior parietal lobe 608, occipital lobe 610, lingual gyrus 612, inferior temporal gyrus 614, medial temporal gyrus 616, superior temporal gyrus 618, orbital frontal lobe 620, pars triangularis 622, pars opercularis 624, supra marginal lobe 626, caudal medial frontal lobe 628, rostral medial frontal lobe (not labeled), superior frontal lobe 630, and frontal pole 632. Additional structures can also be labeled, and the names of the structures can be changed depending on the granularity of the segmentation method used.

FIGS. 6B and C show volume changes within the subject by displaying a color overlay with a color key 650, in which warmer colors represent a percentage increase in volume and cooler colors represent a percentage decrease in volume. The scale used for FIGS. 6B-C is half that of FIG. 5B-C.

The atrophy is progressive but not uniform, particularly affecting the superior temporal gyrus 618, middle temporal gyrus 616, and inferior temporal gyrus 614, with relative sparing of primary sensory areas (pre-central gyrus 604) and motor cortical areas (post-central gyrus 602).

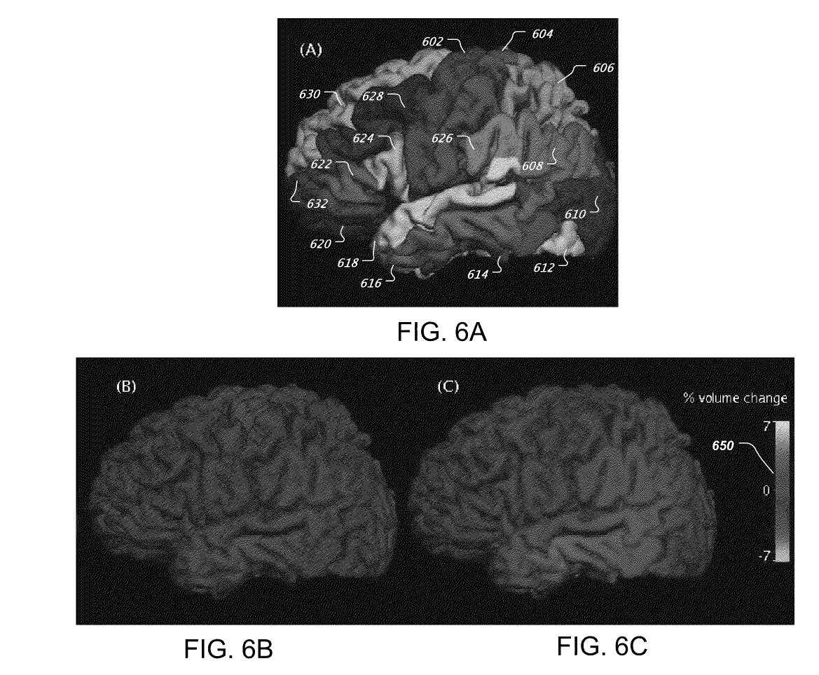

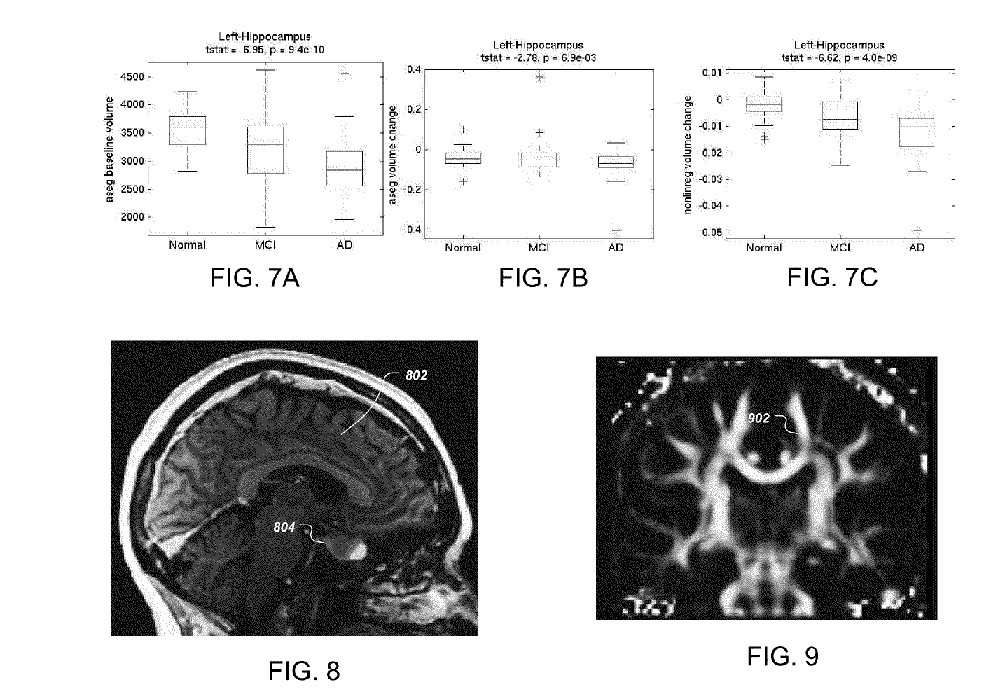

FIGS. 7A-C show example data comparisons for the left hippocampus of normal subjects, MCI subjects, and AD subjects. FIG. 7A compares baseline volumes for the three subject populations; FIG. 7B, volume changes using affine registration and segmented data, and FIG. 7C, volume changes using nonlinear registration techniques and segmented data. Also, for the left hippocampus 516, the decrease in volume at six month intervals was 2.3%, 3.8%, 5%, and 6.7% (accompanying charts not shown).

Tables 2 and 3 give the annualized mean percentage volume change for normal controls and AD subjects for several left- and right-hemisphere ROIs, at six and twelve months, respectively, together with Cohen's-d effect sizes for the AD means and for the AD-normal mean differences. The d-values imply large effect sizes, and indicate that only small populations are needed to distinguish normal from AD ROI atrophy. Early-stage atrophy of the cerebral cortex as a whole is as significant as that of the hippocampus as a hallmark of AD, but greater significance is found specifically within the temporal gyri. Note that the annualized hippocampal volume changes are in general agreement with estimates from manual structure tracing.

TABLE 2
Volume change at six months for normal controls and AD subjects

| | Normal % vol. | | AD % vol. | | Cohen's d | AD |
|---|---|---|---|---|---|---|
| ROI | change | | change | | AD-Normal | only |
| Left middle | −0.38 | (1.30) | −2.55 | (2.08) | −1.25 | −1.23 |
| temporal gyrus | | | | | | |
| Right middle | −0.36 | (1.26) | −2.54 | (1.91) | −1.35 | −1.33 |
| temporal gyrus | | | | | | |
| Left inferior | −0.31 | (1.25) | −2.59 | (2.00) | −1.36 | −1.29 |
| temporal gyrus | | | | | | |
| Right inferior | −0.49 | (1.20) | −2.87 | (2.05) | −1.41 | −1.40 |
| temporal gyrus | | | | | | |
| Left fusiform | −0.24 | (0.97) | −1.81 | (1.41) | −1.30 | −1.29 |
| Right fusiform | −0.23 | (0.98) | −1.78 | (1.44) | −1.25 | −1.23 |
| Left entorhinal | −0.50 | (1.54) | −2.30 | (1.86) | −1.05 | −1.24 |
| cortex | | | | | | |
| Right entorhinal | −0.47 | (1.55) | −2.01 | (2.12) | −0.83 | −0.95 |
| cortex | | | | | | |
| Whole brain | −0.42 | (0.75) | −1.31 | (1.02) | −1.00 | −1.29 |
| Ventricles | 4.45 | (5.90) | 9.62 | (6.54) | 0.84 | 1.47 |
| Left | −0.95 | (1.93) | −3.71 | (2.95) | −1.11 | −1.26 |
| hippocampus | | | | | | |
| Right | −0.79 | (2.04) | −3.14 | (2.60) | −1.01 | −1.21 |
| hippocampus | | | | | | |
| Left temp-horn- | 5.93 | (9.76) | 14.97 | (11.49) | 0.85 | 1.30 |
| lat-vent | | | | | | |
| Right temp-horm- | 5.41 | (9.19) | 15.30 | (11.64) | 0.94 | 1.32 |
| lat-vent | | | | | | |
| Left amygdala | −0.68 | (2.52) | −4.42 | (3.61) | −1.20 | −1.22 |
| Right amygdala | −0.70 | (2.61) | −4.01 | (3.32) | −1.11 | −1.21 |

TABLE 3
Volume change at 12 months for normal controls and AD subjects

| | Normal % vol. | | AD % vol. | | Cohen's d | AD |
|---|---|---|---|---|---|---|
| ROI | change | | change | | AD-Normal | only |
| Left middle | −0.44 | (0.78) | −2.53 | (1.51) | −1.75 | −1.68 |
| temporal gyrus | | | | | | |
| Right middle | −0.45 | (0.81) | −2.52 | (1.63) | −1.60 | −1.54 |
| temporal gyrus | | | | | | |
| Left inferior | −0.39 | (0.77) | −2.62 | (1.60) | −1.77 | −1.64 |
| temporal gyrus | | | | | | |
| Right inferior | −0.47 | (0.80) | −2.66 | (1.57) | −1.76 | −1.70 |
| temporal gyrus | | | | | | |
| Left fusiform | −0.37 | (0.57) | −1.88 | (1.16) | −1.66 | −1.63 |
| Right fusiform | −0.31 | (0.59) | −1.79 | (1.19) | −1.57 | −1.51 |
| Left entorhinal | −0.49 | (1.02) | −2.32 | (1.32) | −1.55 | −1.76 |
| cortex | | | | | | |
| Right entorhinal | −0.49 | (1.19) | −1.96 | (1.12) | −1.28 | −1.76 |
| cortex | | | | | | |
| Whole brain | −0.39 | (0.50) | −1.26 | (0.72) | −1.42 | −1.76 |
| Ventricles | 3.60 | (4.11) | 9.41 | (5.58) | 1.19 | 1.69 |
| Left | −0.95 | (1.30) | −3.67 | (2.00) | −1.61 | −1.83 |
| hippocampus | | | | | | |
| Right | −0.83 | (1.25) | −3.58 | (2.41) | −1.43 | −1.48 |
| hippocampus | | | | | | |
| Left temp-horn- | 4.51 | (6.74) | 14.72 | (8.35) | 1.35 | 1.76 |
| lat-vent | | | | | | |
| Right temp-horm- | 4.39 | (6.39) | 14.74 | (7.86) | 1.45 | 1.87 |
| lat-vent | | | | | | |
| Left amygdale | −0.77 | (1.69) | −3.89 | (2.73) | −1.37 | −1.42 |
| Right amygdale | −0.79 | (1.58) | −3.64 | (2.63) | −1.32 | −1.38 |

TABLE 4
Volume change at six months for stable
MCIs and MCI-to-AD converters

| | | | MCI→AD | | Cohen's d | con- |
|---|---|---|---|---|---|---|
| | Stable MCI % | | converters % | | converter- | verter |
| ROI | vol. change | | vol. change | | stable | only |
| Left middle | −1.29 | (2.02) | −1.87 | (2.09) | −0.28 | −0.90 |
| temporal gyrus | | | | | | |
| Right middle | −1.16 | (2.08) | −1.75 | (2.22) | −0.28 | −0.79 |
| temporal gyrus | | | | | | |
| Left inferior | −1.16 | (1.99) | −2.04 | (2.13) | −0.43 | −0.96 |
| temporal gyrus | | | | | | |
| Right inferior | −1.20 | (1.93) | −2.01 | (2.30) | −0.38 | −0.87 |
| temporal gyrus | | | | | | |
| Left fusiform | −0.85 | (1.47) | −1.65 | (1.51) | −0.54 | −1.09 |
| Right fusiform | −0.73 | (1.34) | −1.31 | (1.55) | −0.40 | −0.85 |
| Left entorhinal | −1.61 | (1.90) | −2.22 | (2.17) | −0.30 | −1.02 |
| cortex | | | | | | |
| Right entorhinal | −1.52 | (2.10) | −1.85 | (1.86) | −0.16 | −0.99 |
| cortex | | | | | | |
| Whole brain | −0.77 | (1.04) | −1.09 | (1.29) | −0.27 | −0.85 |
| Ventricles | 6.09 | (7.47) | 8.05 | (8.75) | 0.24 | 0.92 |
| Left | −2.14 | (3.00) | −2.61 | (3.28) | −0.15 | −0.80 |
| hippocampus | | | | | | |
| Right | −2.06 | (2.67) | −2.61 | (3.60) | −0.17 | −0.72 |
| hippocampus | | | | | | |
| Left temp-horn- | 8.98 | (12.31) | 11.52 | (12.35) | 0.21 | 0.93 |
| lat-vent | | | | | | |
| Right temp-horm- | 8.48 | (10.57) | 11.54 | (13.11) | 0.26 | 0.88 |
| lat-vent | | | | | | |
| Left amygdale | −2.21 | (3.74) | −3.11 | (3.53) | −0.25 | −0.88 |
| Right amygdale | −2.12 | (3.12) | −4.26 | (4.00) | −0.60 | −1.07 |

TABLE 5

| | | | MCI→AD | | Cohen's d | con- |
|---|---|---|---|---|---|---|
| | Stable MCI % | | converters % | | converter- | verter |
| ROI | vol. change | | vol. change | | stable | only |
| Left middle | −1.26 | (1.31) | −2.12 | (1.34) | −0.65 | −1.59 |
| temporal gyrus | | | | | | |
| Right middle | −1.16 | (1.33) | −2.15 | (1.59) | −0.67 | −1.35 |
| temporal gyrus | | | | | | |
| Left inferior | −1.18 | (1.24) | −2.19 | (1.37) | −0.77 | −1.60 |
| temporal gyrus | | | | | | |
| Right inferior | −1.17 | (1.31) | −2.27 | (1.67) | −0.73 | −1.35 |
| temporal gyrus | | | | | | |
| Left fusiform | −0.92 | (0.96) | −1.59 | (1.01) | −0.68 | −1.58 |
| Right fusiform | −0.81 | (0.93) | −1.58 | (1.15) | −0.74 | −1.37 |
| Left entorhinal | −1.57 | (1.55) | −2.26 | (1.47) | −0.45 | −1.53 |
| cortex | | | | | | |
| Right entorhinal | −1.23 | (1.56) | −2.02 | (1.47) | −0.52 | −1.38 |
| cortex | | | | | | |
| Whole brain | −0.68 | (0.58) | −1.14 | (0.77) | −0.68 | −1.48 |
| Ventricles | 5.67 | (5.55) | 8.50 | (5.15) | 0.53 | 1.65 |
| Left | −1.80 | (2.14) | −2.94 | (2.24) | −0.52 | −1.31 |
| hippocampus | | | | | | |
| Right | −1.76 | (2.18) | −2.62 | (2.13) | −0.40 | −1.23 |
| hippocampus | | | | | | |
| Left temp-horn- | 8.73 | (8.72) | 13.64 | (9.28) | 0.55 | 1.47 |
| lat-vent | | | | | | |
| Right temp-horm- | 8.60 | (7.24) | 12.83 | (9.27) | 0.51 | 1.38 |
| lat-vent | | | | | | |
| Left amygdala | −2.43 | (2.61) | −3.81 | (2.96) | −0.49 | −1.29 |
| Right amygdala | −2.28 | (2.28) | −3.52 | (2.19) | −0.55 | −1.60 |

Mean (standard deviation) annualized percent volume change at twelve-months for MCI nonconverters (n = 116) and MCI to AD converters (n = 47), and the corresponding Cohen's d for the converter-nonconverter mean difference and nonconverter means alone.

This example shows that serial magnetic resonance imaging (MRI) and clinical and neuropsychological assessment can be combined to measure the progression of MCI and early AD. Determination of sensitive and specific markers of very early AD progression is intended to aid researchers and clinicians to develop new treatments and monitor their effectiveness, as well as lessen the time and cost of clinical trials.

### Example 3

### Detection of Pituitary Tumor

The nonlinear registration method, system, and techniques can also be applied to subjects with tumors to highlight and assess tumor growth, and to register pre- and post-operation structural and diffusion-tensor-imaging scans. An example of the former is a subject with a pituitary tumor, shown in FIG. 8, in which an overlay volume-change field shows that a majority of the subject's brain 802 does not change volume, but that a tumor 804 does experience growth. By defining a baseline segmentation for the pituitary, it will be possible to quantify its structural change.

### Example 4

### White Matter Tracts in Epilepsy

FIG. 9 shows the fractional anisotropy (FA) map that highlight white matter tracts 902, after resection in the subject's right temporal lobe, mapped back to coincide with the pre-operation FA map. Pre- and post-operation structural images have also been registered.

### Example 5

### Longitudinal Changes in the Developing Primate Brain

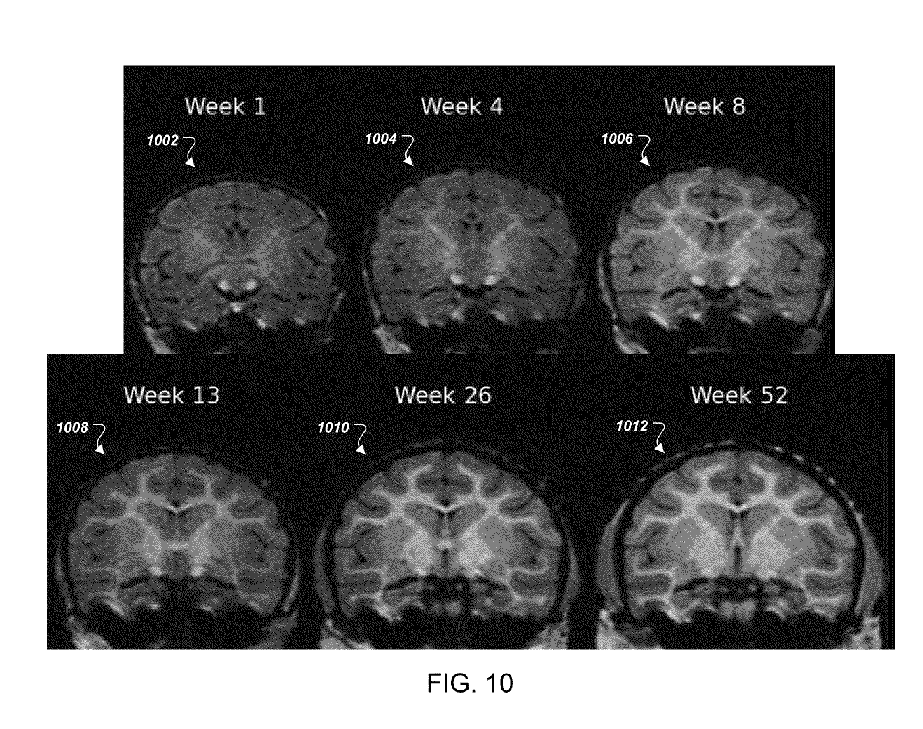

Brain development is another area of application for the system and techniques for longitudinal analysis of a subject. As shown in FIG. 10, registration methods were applied to MRI scans of monkeys, beginning one week after birth. Data is displayed for the following development intervals: one week (image 1002), four weeks (image 1004), eight weeks (image 1006), 13 weeks (image 1008), 26 weeks 9 image 1010), and 52 weeks (image 1012) of development. Substantial brain growth and myelination of white matter is visible. With nonlinear registration, anatomically similar regions we located between any pair of scans to quantify brain development. This application is also be applicable to human neonatal development.

While this specification contains many specifics, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Only a few implementations and examples are described and other implementations, enhancements and variations can be made based on what is described and illustrated in this application.

What is claimed is:

1. A method for imaging a subject, comprising:
correcting first and second images of a subject and registering the first image to the second image;
obtaining a deformation field that maps each element in the first image into a corresponding element in the second image by reducing a mapping error from the first image to the second image; and
calculating a volume of at least one region within the subject in the second image and using the deformation field to calculate a volume of the same at least one region within the subject in the first image.

2. The method of claim 1, in which the first and second images comprise images measured with magnetic resonance imaging, x-ray computed tomography, ultrasound, single photon emission computed tomography, or positron emission tomography.

3. The method of claim 1, in which the subject comprises a human, a primate, or a rodent.

4. The method of claim 1, in which the registering comprises performing an affine registration prior to a nonlinear registration.

5. The method of claim 1, comprising smoothing the images as part of registering the first image to the second image.

6. The method of claim 5, in which registering comprises iteratively smoothing the images and performing a nonlinear registration of the first image to the second image.

7. The method of claim 1 in which minimizing comprises calculating a Hessian of a function that represents the mapping error and using a linear algebraic technique on the Hessian to obtain the deformation field.

8. The method of claim 7, in which the linear algebraic technique comprises conjugate gradients squared (CGS), generalized minimal residuals (GMRES), or biconjugate gradients stabilized method (Bi-CGSTAB).

9. The method of claim 1, in which the minimizing is computationally fast.

10. The method of claim 1 in which correcting comprises:
standardizing intensities of the images to a uniform intensity scale; and
locally rescaling the intensities in the first or the second image to conform with inhomogenieties in the other image.

11. The method of claim 1, in which correcting comprises correcting geometric image distortions.

12. The method of claim 1, in which the at least one region within the subject is identified by using an automatic or manual segmentation technique.

13. The method of claim 1, in which the at least one region comprises part of a brain, a liver, a knee, a heart, an abdomen, or an organ.

14. The method of claim 1, in which the at least one region comprises part of a hippocampus, a middle temporal gyrus, an inferior temporal gyrus, a fusiform gyrus, an entorhinal cortex, a ventricle, or an amygdala.

15. The method of claim 1, comprising quantifying a volumetric change in the first and second images of the region within the subject.

16. The method of claim 15, in which the method is used for detection of a pathology or a disease.

17. The method of claim 16, in which the disease comprises a neurodegenerative disorder, a cancer, an inflammatory disease, or an immunologic disease.

18. The method of claim 17, in which the neurodegenerative disorder comprises Alzheimer's Disease.

19. The method of claim 15, in which the method is used to assess an efficacy of a treatment administered to the subject.

20. The method of claim 19, in which the treatment comprises a drug or radiation therapy.

21. The method of claim 15, comprising evaluating groups of subjects with the method.

22. The method of claim 15, comprising producing a visualization of the volumetric change between the first and second images of the region within the subject.

23. The method of claim 22, in which the visualization comprises a color image whose color represents the volumetric change.

24. The method of claim 1, in which the first image is measured at a time before or after the second image and the time comprises days, weeks, months, and years.

25. The method of claim 1, in which the contrasts of the first and second images comprise contrasts based on different image weightings or modalities.

26. The method of claim 1, in which the mapping error comprises a function that comprises terms representing gradients of displacements at each voxel of one image of the pair, amplitudes of the displacements, and a quality of the registration.

27. A method for imaging an object, comprising:
providing a function that represents a registration error between of a pair of images of an object;
reducing the function to correct for at least one of relative intensity variation or relative structural deformation between the images; and
producing a deformation field that registers one image of the pair to the other image of the pair.

28. The method of claim 27, comprising quantifying a volumetric change between the images.

29. The method of claim 27, in which the function comprises terms representing gradients of displacements at each voxel of one image of the pair, amplitudes of the displacements, a quality of the registration, or other quantities.

30. A method for diagnosing or monitoring a progress of a pathology or a disease, comprising:
correcting first and second images of a subject and registering the first image to the second image;
obtaining a deformation field that maps each element in the first image into a corresponding element in the second image by minimizing, on a computer, a mapping error from the first image to the second image;
calculating a volume of at least one region within the subject in the second image and using the deformation field to calculate a volume of the same at least one region within the subject in the first image; and
quantifying a volumetric change in the first and second images of the region within the subject, in which the volumetric change at least in part determines a presence or a change in the pathology or the disease.

31. The method of claim 30, in which determining a presence or a change comprises comparing the volumetric change with data of an expected change in the pathology or the disease.

32. A method of assessing an effect of a compound on a specified brain region, comprising the use of the method of claim 15, in which the volumetric change indicates the efficacy of the compound.

33. A computer program product, encoded on a computer-readable medium, operable to cause a data processing apparatus to perform operations comprising:
obtaining a first image of a subject and a second image of the subject, in which the first image is measured at a different time than the second image;
correcting the first and second images;
registering the first image to the second image;
obtaining a deformation field that maps each element in the first image into a corresponding element in the second image by minimizing a function that represents a mapping error between the first and second images; and
calculating a volume of at least one region within the subject in the second image and using the deformation field to calculate a volume of the same at least one region within the subject in the first image.

34. The computer program product of claim 33, comprising operations for quantifying a volumetric change in the first and second images of the region within the subject.

35. A magnetic resonance imaging system comprising:
a magnetic resonance system configured to provide a first image and a second image of a subject; and
a data processing system configured to
correct the first and second images;
register the first image to the second image;
obtain a deformation field that maps each element in the first image into a corresponding element in the second image by minimizing a function that represents a mapping error between the first and second images; and
calculate a volume of at least one region within the subject in the second image and using the deformation field to calculate a volume of the same at least one region within the subject in the first image.

36. The system of claim 35, comprising a data processing system configured to quantify a volumetric change in the first and second images of the region within the subject.
